(19) United States
(12) Patent Application Publication
(10) Pub. No.: US 2009/0153145 A1
(43) Pub. Date: Jun. 18, 2009

(54) Method and Device for Checking Current Converters by Means of High-Current Pulses

(75) Inventors: Markus Engel, Nürnberg (DE); Harald Karl, Fürth (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, Munchen (DE)

(21) Appl. No.: 12/298,588

(22) PCT Filed: Apr. 18, 2007
(86) PCT No.: PCT/EP07/53763

§ 371 Date: Oct. 27, 2008

(30) Foreign Application Priority Data
Apr. 25, 2006 (DE) 10 2006 020 086.1

(51) Int. Cl. G01R 33/02

(52) U.S. Cl. 324/537

(57) ABSTRACT

In order to check the functionality of a conventional current converter at low cost, a device for checking a current converter is provided. The current converter includes a test current conductor and a test pulse circuit. The latter has an energy storage device, a charging device for charging the energy storage device and a switching element for discharging the energy storage device via the test current conductor. As a result, a discharge current can be generated in the test current conductor, wherein an evaluation unit for detecting a current converter signal caused by the discharge current is provided.

The invention relates to a device and a method for checking a current converter.

Current converters are used in energy distribution and transmission, and for example in supplying energy to rail-mounted vehicles such as the Transrapid. They are usually used for monitoring the current flow in a primary current conductor which is on a high voltage potential. The current converter generates in the low-voltage domain an output signal which is proportional to the current flow in the primary conductor and can be processed by post-connected switching devices or control units.

In order that the failure of a current converter can be detected, the error-free function of the current converter must usually be checked cyclically. Such checks are necessary especially if the current converter is part of a facility for which there are high safety requirements. For the execution of a function test, a current converter with an additional test winding is provided according to prior art. The test winding is put on a core of the current converter, on which the secondary winding of the current converter is also provided. The primary winding of the current converter is usually a conductor which interacts over the core with the secondary winding and can also be regarded as a winding with the winding number 1. The test winding, on the other hand, usually has several thousand windings, so that a large primary current can be simulated with a small test current. The test winding is usually cast in an insulator of the current converter. It significantly increases the cost of the current converter.

It is therefore the object of the invention to provide a device and a method of the kind initially mentioned, which enable checking of conventional and economical current converters.

The invention achieves this object according to a first variant with a device for checking a current converter with a test current conductor and a test pulse circuit, which has an energy store, charging means for charging the energy store and a switching element for discharging the energy store via the test current conductor, so that a discharge current can be generated in the test current conductor, an evaluation unit being provided for detecting a current converter signal caused by the discharge current.

The invention achieves this object according to a second variant with a method for checking a current converter, in which a test current conductor is led at least once through the current converter and then the outputs of a test pulse circuit are combined together by means of the test current conductor, an energy store is charged, then a switching element is actuated to discharge the energy store, generating a discharge current flowing over the test current conductor, and the current converter signal generated by the current converter as a result of the discharge current is measured.

According to the invention, a device and a method are provided, with which the checking of the proper functioning of current converters is enabled, which have no expensive test winding and which are consequently economical. According to the invention, the functional checking of current converters that are already permanently installed is furthermore also possible. The device according to the invention contains a test pulse circuit, whose output or outputs are short-circuited by an optionally selectable test current conductor. This test pulse circuit contains an energy store and a switching element. Actuation of the switching element causes a discharge of the energy store, resulting in a high discharge current in the test current conductor. The energy transferred to the energy store is sufficient according to the invention to generate a discharge current so high that the secondary current at the output of the current converter to be checked can be detected by the installed evaluation unit. The evaluation unit could be one that is also connected to the current converter in normal operation. In a departure from this, the evaluation unit is an evaluation unit to be additionally connected at the output for the checking of the current converter. The energy store can also be inductively coupled with the test current conductor, for example. It is essential within the scope of the invention that a high current is generated in the test current conductor by the discharge of the energy store.

The energy store is a coil, for example. The coil can be disposed in a shorted circuit, in which the switching element and the charging means are additionally disposed. The test current conductor is disposed in parallel to the coil. If the switching element is in its contact setting in which a current flow over the switching element is enabled, a charging current generated by the charging means flows in the shorted circuit. The impedance of the test current conductor connected in parallel to the coil is so high that the current flowing over the test current conductor can be ignored. The triggering of a switching operation causes the switching element to open. The current flow in the shorted circuit is interrupted.

The coil is then discharged over the test current conductor, resulting in a high discharge current.

According to a preferred development of the invention, the energy store is a capacitor, the switching element being switched in series with the capacitor. If the switching element is in its disconnected position, the capacitor is charged by the charging means. The falling voltage on the capacitor is called the charging voltage. The triggering of a switching operation enables a discharge of the capacitor over the switching element and ultimately over the selected test current conductor. The capacitor usefully has a capacity which, depending on the charging voltage achievable for the capacitor with the charging means, is sufficient to generate a discharge current so high that this generates a detectable secondary current at the output of the current converter.

The switching element is usefully a semiconductor switch, which can be switched from a lock position, in which a current flow is enabled over the power semiconductor, to a through position, in which a current flow over the power semiconductor is interrupted. Switchable power semiconductors are e.g. thyristors, IGBTs or similar. Semiconductor switches enable fast switching in comparison to mechanical switches. An unwanted influence of the switching operation on the pulse form of the discharge current can be avoided in this way.

An advantageous development provides at least two test current conductors disposed in parallel and a relay, which is set up to connect one of the test current conductors to the output test pulse circuit. In this way, several current converters can be tested with a common test pulse circuit. In a departure from this, several thyristors are provided, each assigned to one test current conductor. Firing a particular thyristor thus enables selection of the current converter to be tested.

In a departure from this, at least two test current conductors disposed in series are provided. Several current converters can be simultaneously tested by this means. Naturally, any combinations of test current conductors disposed in parallel to each other and in series are possible within the scope of the invention.

The test current conductor is for example permanently integrated in the current converter, where however it has only a limited number of windings.

According to an advantageous development of the first variant, however, the test current conductor is flexible. Because of the flexible development of the test current conductor, it can especially easily be subsequently fitted to the current converter. If the current converter has a closed rotary toroidal core, for example, the test conductor is for example fed by hand through the toroidal core. The test current conductor is then switched in parallel to the primary conductor.

The device according to the invention and the method according to the invention are suitable both for current converters working inductively and also for current converters which are based on the so-called Hall effect.

In a further advantageous development according to the first variant of the invention, the test pulse circuit contains a limiting inductance in series connection to the energy store. The limiting inductance limits the discharge current to a certain measure, so that the size of the discharge current can be more precisely set in the design of the test pulse circuit.

The test pulse circuit advantageously has regulating means for setting the charging voltage of the energy store. The regulating means enable the charging voltage of the capacitor to be set dependent on the length of the test current conductor, for example. This can be advantageous in particular if the test pulse circuit is connected to several test current conductors, each of which is led through an assigned current converter. In this case the test pulse circuit has an additional relay, which enables the selection of the test current conductor which carries the discharge current as a result of the switching. In other words, the relay switches the individual selected test current conductor parallel to the series connection of capacitor and power semiconductor. However, the regulating means can also set the size of a current flowing over a coil as energy store. In this context, reference is made to the above explanations on the coil.

The test pulse circuit further enables the impressing of a specific curve shape on the discharge current.

According to a development useful in this context, the regulating means contain a shunt resistor disposed in series to the energy store for measuring the curve shape of a discharge current flowing over the shunt resistor. The shunt resistor is usefully an ohmic resistor. The voltage drop at this shunt resistor is measured, the detected voltage signal then being converted into current values. The comparison of the curve shape of the secondary current detected at the current converter's output with the curve shape of the impressed discharge current allows additional statements about the proper functioning of the respective checked current converter. Alternatively, the curve shape can also be achieved with an inductive coupling (repeating coil or pcb structures) of the generated discharge current with the evaluation circuit.

According to an advantageous development of the method according to the invention, the quantity of the energy store's energy is regulated. In the case of a capacitor, the regulating means regulate the capacitor's charging voltage. This enables both adaptation of the charging voltage to different lengths of the test current conductor, and also resetting of the charging voltage dependent on the aging of the capacitor.

Advantageously, the test current conductor is laid between two and twenty times through the current converter. Multiple passing of the test current conductor through the current converter simulates a higher primary current for the same test current circuit, thereby extending the possibilities of the method according to the invention. The size of the test current can naturally also be set by regulating the stored energy.

According to a further useful development of the method according to the invention, a specific curve shape is impressed on the discharge current. The comparison of the curve shape of the impressed discharge current with the curve shape of the secondary current caused at the current converter's output expands the possibilities for information about the proper functioning of the respective current converter.

The discharge current is advantageously limited by a limiting inductance. The limiting of the discharge current enables a more precise setting of the discharge current dependent on the charging means and also dependent on the quantity of stored energy.

The charging means are implemented with a switched-mode power supply, for example. Such switched-mode power supplies usefully comprise a DC voltage source in the form of a battery or similar, which is connected to a winding of a transformer or repeating coil. The charging means further have, for example, in series to the winding, a switch, for example in the form of a semiconductor switch, so that depending on the said switch's position a change of the direct current flowing over the primary winding of the said capacitor between zero and a maximum direct current can be generated. This “chopping up” of the direct current causes a secondary current to be generated at the transformer. If the energy store is a capacitor, the secondary current thus generated is rectified by a diode and then used to charge the capacitor. As a result of the chopping up of the direct current with the switch and the feedback of the actual value of the energy store's charge state to the regulating circuit, regulation of the energy stored in the energy store is further enabled.

The implementation of the energy store is in no way limited to coils or capacitors. In principle any energy stores are possible which can be sufficiently quickly discharged with the switching element.

Further useful developments and advantages of the invention are the subject of the description that follows of embodiments of the invention with reference to the figures of the drawings, where identical reference labels refer to identically working components, and where

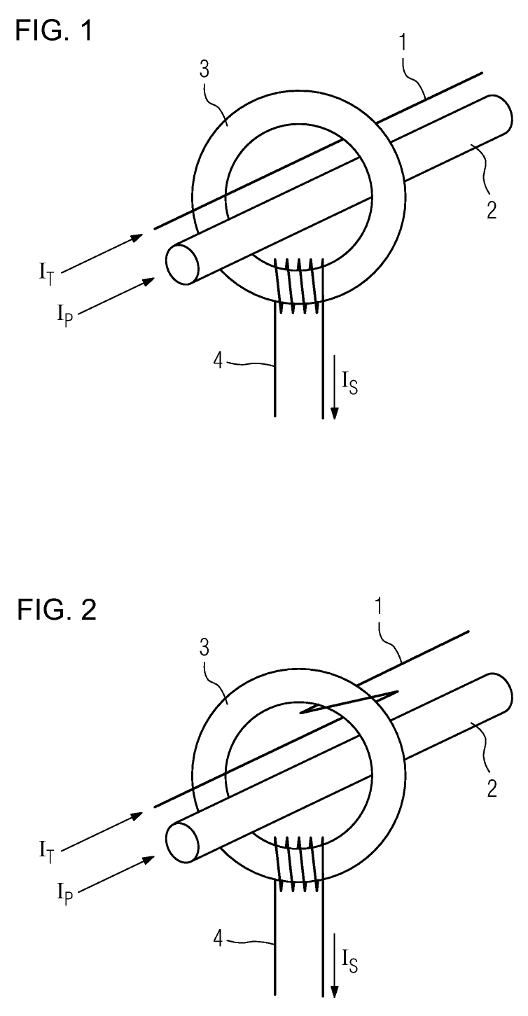

FIG. 1 shows an embodiment of the device according to the invention with a test current conductor led once through the current converter,

FIG. 2 an embodiment of the device according to the invention with a test current conductor led twice through a current converter, and

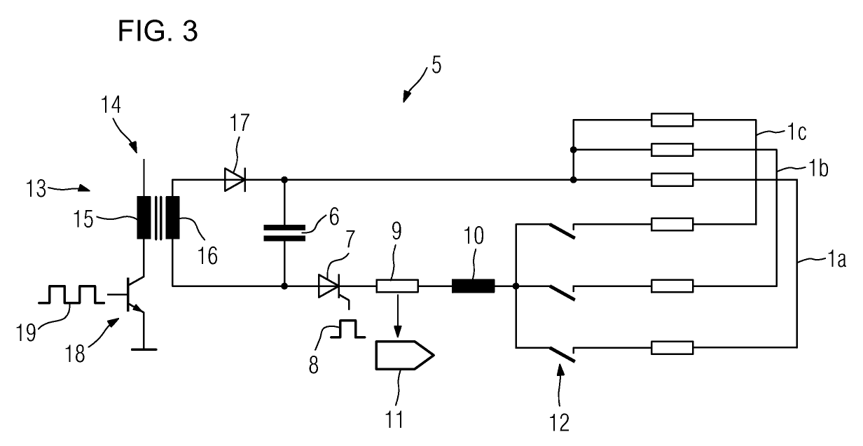

FIG. 3 an embodiment of the test pulse circuit of the device according to the invention.

FIG. 1 shows an embodiment of the device according to the invention, with a test current conductor 1 which is led parallel to a primary current conductor 2 through a toroidal core 3 of a current converter. In addition to an insulator not shown in the figure, the current converter contains a secondary winding 4, which with the toroidal core 3 is permanently embedded in the insulator. By impressing a sufficiently high test current I_{T}, a secondary current I_{S} can be generated at the output of the current converter by inductive coupling between the test current conductor 1 and the secondary winding 4, and is led to an evaluation unit not shown in the figure. If the size of the impressed discharge current is known, it is possible for example to check the calibration of the current converter and thus the functioning of the current converter.

FIG. 2 shows a test current conductor 1, which is led twice through the toroidal core 3 of the current converter. This test current conductor 1 is connected to the same test pulse circuit as the embodiment shown in FIG. 1. As a result of the double passing of the test current conductor 1 through the toroidal core 3, a winding with a winding number of n equals 2 is thus provided, with which a higher primary current Iₚ can be simulated than in the embodiment shown in FIG. 1.

FIG. 3 shows an embodiment of a test pulse circuit 5, which has a capacitor 6 and a switchable power semiconductor in the form of a thyristor 7. The thyristor 7 can be fired with starting pulses 8 by a firing circuit not shown in FIG. 3, so that the thyristor 7 can be switched from a lock position, in which a current flow over the thyristor 7 is interrupted, to a through position, in which a current flow over the thyristor 7 is enabled.

An ohmic shunt resistor 9 and a limiting inductance 10 are further disposed in series to the thyristor 7. The falling voltage on the shunt resistor 9 is detected as the voltage signal, the received voltage signal being sampled by sampling means obtaining samples, and the samples being converted by an analog-digital converter into digital voltage values. The voltage values are then converted into digital current values 11. The sampling rate of the voltage signals is so high that it is possible to detect the curve shape of a discharge current, which can be generated by short-circuiting of the capacitor 6. Such a discharge current is advantageously in pulse form, and has for example a half-width of 3 ms, the half-width being measured as total width, which the current pulse has at the half of its maximum.

The test pulse circuit shown in FIG. 3 further has a relay 12, which enables a selection of which of the parallel-switched test current conductors 1a, 1b or 1c the discharge current flows over. According to this embodiment of the invention, only one test pulse circuit is thus needed for checking three current converters, each current converter being assigned only one test current conductor 1a, 1b or 1c in each case.

The test current circuit 5 further contains charging means 13, which include a DC voltage source not shown in the figure, and a transformer 14 with a primary winding 15 and a secondary winding 16. The charging means 13 further have a rectifier diode 17 and a semiconductor switch 18. The firing of the semiconductor switch 18 in a specific pulse sequence 19 causes the semiconductor switch to be moved periodically from its through position to its lock position. Such a periodic change of the switch position of the semiconductor switch 18 causes the current flow over the secondary winding 15 to be effectively chopped up, and a corresponding secondary current to be generated in the secondary winding 16. The secondary current is then rectified through the rectifier diode 17, leading to the charging of the capacitor 6. The charging voltage of the capacitor 6 is dependent firstly on the selected DC voltage source and also on the activation of the semiconductor switch 18, and can be set with regulating means which are not shown in the figure.

The charging voltage of the capacitor 6 furthermore also influences the curve shape and the amplitude of the discharge current. Regulating means are provided for this, the regulating means receiving over a suitable communication line the current curve values measured at the shunt resistor 9, and comparing the resulting curve shape of the discharge current with a predefined reference curve. If the deviation is too great, an internal logic is used to generate a charging voltage reference value, which is passed to a subordinate voltage control which uses a suitable pulse sequence 19 to set a charging voltage for the capacitor 6 corresponding to the charging voltage reference value.

1-17. (canceled)

18. A device for checking a current converter, comprising:
a test current conductor;
a test pulse circuit connected to said test current conductor, said test pulse circuit having an energy storage device, charging means for charging said energy storage device, and a switching element for discharging said energy storage device through said test current conductor for generating a discharge current in said test current conductor; and
an evaluation unit for detecting a current converter signal caused by the discharge current.

19. The device according to claim 18, wherein said test current conductor is guided through said current converter at least once.

20. The device according to claim 18, wherein said energy storage device is a capacitor and said switching element is connected in series with said capacitor.

21. The device according to claim 18, wherein said switching element is a power semiconductor switch that is switchable from a blocking position, in which a current flow is disabled over a power semiconductor, to a through position, in which a current flow over said power semiconductor is enabled.

22. The device according to claim 18, wherein said test current conductor is one of at least two test current conductors disposed in parallel and wherein a relay is configured to selectively connect one of said test current conductors to an output of said test pulse circuit.

23. The device according to claim 18, wherein said test current conductor is one of at least two test current conductors connected in series.

24. The device according to claim 18, wherein said test current conductor is a flexible conductor.

25. The device according to claim 18, wherein said test pulse circuit has a limiting inductance connected in series with said energy storage device.

26. The device according to claim 18, wherein said test pulse circuit has regulating means for selecting a stored energy of the energy storage device.

27. The device according to claim 26, wherein said regulating means include a shunt resistor disposed in series to said energy storage device for measuring a curve shape of a discharge current flowing over said shunt resistor.

28. A method for checking a current converter, which comprises:
guiding a test current conductor at least once through the current converter and then connecting the outputs of a test pulse circuit to one another by way of the test current conductor;
charging an energy storage device;
subsequently actuating a switching element to discharge the energy storage device, and generating a discharge current flowing over the test current conductor; and
measuring a current converter signal generated by the current converter as a result of the discharge current.

29. The method according to claim 28, which comprises regulating a quantity of the energy stored in the energy storage device by closed-loop control.

30. The method according to claim 28, which comprises guiding the test current conductor through the current converter between two and twenty times.

31. The method according to claim 28, which comprises impressing a specific curve shape on the discharge current.

32. The method according to claim 28, which comprises limiting the discharge current by a limiting inductance.

33. The method according to claim 28, which comprises providing at least two test current conductors in parallel and switching a relay in such a way that the discharge current flows over a respectively selected test current conductor.

34. The method according to claim 28, which comprises connecting at least two test current conductors in series, and conducting the discharge current over each test current conductor.
